(19) United States
(12) Patent Application Publication
(10) Pub. No.: US 2019/0093842 A1
(43) Pub. Date: Mar. 28, 2019

(54) PRIMARY OPTICS LIGHT SOURCE WITH RECTANGULAR LIGHT PATTERN

(71) Applicant: UNITY OPTO TECHNOLOGY CO., LTD., NEW TAIPEI CITY (TW)

(72) Inventors: Ching-Huei Wu, NEW TAIPEI CITY (TW); Yung-Ching Hu, NEW TAIPEI CITY (TW); Cheng-Chien Ou, NEW TAIPEI CITY (TW); Wei-Chung Lin, NEW TAIPEI CITY (TW)

(21) Appl. No.: 16/199,260

(22) Filed: Nov. 26, 2018

Related U.S. Application Data
(63) Continuation-in-part of application No. 15/342,597, filed on Nov. 3, 2016.

(30) Foreign Application Priority Data
Jun. 24, 2016 (TW) 105119903

(51) Int. Cl. F21S 41/143; F21S 41/29; F21K 9/65; H01L 33/54

(52) U.S. Cl. CPC F21S 41/143; F21S 41/29; F21Y 2115/10; H01L 33/54; F21K 9/65

(57) ABSTRACT

Disclosed is a primary optics light source with a rectangular light pattern including a substrate, an LED chip and an encapsulated package. The LED chip is installed on the substrate, and the encapsulated package covers the LED chip to fix the LED chip. A light of the LED chip is emitted to the outside through the encapsulated package to form a rectangular light pattern, so that when the light source is lit, a specific rectangular illumination light pattern is formed.

### CROSS-REFERENCE TO RELATED APPLICATIONS

This application is a continuation-in-part patent application of U.S. application Ser. No. 15/342,597 filed on Nov. 3, 2016, the entire contents of which are hereby incorporated by reference for which priority is claimed under 35 U.S.C. § 120.

### FIELD OF THE INVENTION

The present invention relates to the field of light emitting diodes (LEDs), and more particularly to a LED die packaging structure capable of producing a rectangular light pattern in the primary optics.

### BACKGROUND OF THE INVENTION

### 1. Description of the Related Art

Light emitting diode (LED) with the advantages of excellent color rendering and light emission efficiency has become a main light source for various different lamps. At present, a general LED just has a basic light dispersion capability after it is packaged. When it is necessary to form an LED light source with a specific light pattern, one or more optical elements such lenses or mirrors must be used, and the optical light reflection feature is used to emit lights with various illumination light patterns according to the LED light source, and such design of optical elements used for purposes other than the LED light source is generally called as “secondary optics design”. In addition to the lenses and mirrors, a common lamp housing design also falls in the category of secondary optics design.

To ensure the safety of driving, an automobile lamp must be in compliance with related laws and regulations on its brightness, angle of illumination, and light pattern of illumination. If an LED light source is applied in the field of automobile lamps, and the required light pattern is in a rectangular shape, most manufacturers adopt the secondary optics technology to design the automobile lamps due to the light output limitation of the LED light source. For example, a lens is added to the luminous light path of the LED to gather light and adjust the light pattern projected to the outside, so as to improve the illumination brightness of the LED and meet the light pattern requirement.

To adjust the light pattern from a scattered form into a rectangular form after the light passes the light through the lens of the lamp, the whole structural design of the lamp must take various complicated control factors into consideration, and thus increasing the level of inconvenience and difficulty of the design. In addition, the dimensions and specifications of the lamp various according to different models of motor vehicles. Therefore, finding a method of stably providing the required light pattern for different dimensions and specifications of the LED light source of motor vehicles and simplifying the structural design of the lamp demands immediate attentions and feasible solutions. Therefore, the inventor of the present invention bases on the idea of LED packaging technology of a light source to provide a primary optics light source with a rectangular light pattern to simplify the structure of the lamp and lowering the design and production costs of the lamp.

### SUMMARY OF THE INVENTION

Therefore, it is a primary objective of the present invention to provide a primary optics light source with a rectangular light pattern, and the primary optics light source is capable of directly forming a rectangular illumination light pattern when the light source is lit to achieve the effects of simplifying the structure of a lamp and lowing the installation and development costs.

To achieve the aforementioned and other objectives, the present invention discloses a primary optics light source with a rectangular light pattern in a preferred embodiment, the primary optics light source comprises a substrate, an LED chip and an encapsulated package, wherein the LED chip is installed at the substrate, and the encapsulated package covers the LED chip to fix it to the substrate, characterized in that a cross-section profile of the encapsulated package in x-axis is a compound curve having three pairs of arcs of successively different radii joined tangentially without reversal of curvature, the compound curve comprises five discontinuities where slopes cannot be defined at the five discontinuities, and a cross-section of the encapsulated package in y-axis comprises a hyperbolic curve; wherein the x-axis and the y-axis are perpendicular to each other, and a plane included between the x-axis and the y-axis is parallel to a plane of the substrate provided for installing the LED chip. Therefore, the primary optics light source can be lit through the encapsulated package to directly form the required rectangular light pattern without using the remaining optical elements for a secondary optics design.

Preferably, when the LED chip has a size of 55 mil, the rectangular light pattern has an aspect ratio falling within a range of 3.6:1-3.9:1; and when the LED chip has a size of 38 mil, the rectangular light pattern has an aspect ratio falling within a range of 5.45:1-5.75:1.

Before the encapsulated package is combined with the substrate, the substrate includes an adhesive for improving the bonding strength between the encapsulated package and the substrate. Preferably, the encapsulated package is made of silicone to provide excellent packaging and light transmission performance.

In another preferred embodiment, both ends of the encapsulated package may be reduced slightly to decrease the total length along the y-axis without affecting light pattern projected from the primary optics light source. When it is necessary to reduce the length of the encapsulated package in the y-axis, both ends of the encapsulated package are removed, so that the cross-section of the encapsulated package in the y-axis has a pair bent section.

Similarly, when the LED chip has a size of 55 mil, the rectangular light pattern has an aspect ratio falling within a range of 2.25:1-2.55:1; and when the LED chip has a size of 38 mil, the rectangular light pattern has an aspect ratio falling within a range of 3.5:1-3.8:1.

Before the encapsulated package is combined with the substrate, the substrate includes an adhesive for improving the bonding strength between the encapsulated package and the substrate. Preferably, the encapsulated package is made of silicone to provide excellent packaging and light transmission performance.

In summation, the primary optics light source of the present invention is capable of directly obtaining a rectangular illumination light pattern in the primary optics design without requiring a secondary optics design to improving the application performance of the light source, so that the automotive lamp may skip the complicated structural design of the lamp and reduce the quantity of optical elements used, so as to reduce the total volume of the lamp. With the encapsulated package, the light emitted to the outside through the LED chip can be adjusted effectively to directly form the rectangular light pattern and maintain an excellent light output quality. In addition, the encapsulated package still maintain the rectangular light pattern of the primary optics light source and the same aspect ratio of the rectangular light pattern under the conditions of changing the proportion of its size or changing the specification of the LED chip. In addition, if the length of the encapsulated package is reduced in the y-axis, the rectangular light pattern of the primary optics light source will not be changed or affected. Therefore, the present invention improves the inconvenience of the light source of the conventional automotive lamp that requires a secondary optics design to form a specific light pattern, and thus the present invention further has the effect of lowering the design and development cost of the automotive lamp.

### BRIEF DESCRIPTION OF THE DRAWINGS

FIG. 1 is a perspective view of a preferred embodiment of the present invention;

FIG. 2 is a cross-sectional view of the preferred embodiment of the present invention along the x-axis;

FIG. 3 is another cross-sectional view of the preferred embodiment of the present invention along the x-axis;

FIG. 4 is a cross-sectional view of the first embodiment of the present invention along the y-axis;

FIG. 5 shows a first light distribution curve of the preferred embodiment of the present invention;

FIG. 6 shows a second light distribution curve of the preferred embodiment of the present invention;

FIG. 7 is a schematic view showing an application of the preferred embodiment of the present invention; and

FIG. 8 is a cross-sectional view of a second embodiment of the present invention along the y-axis.

### DESCRIPTION OF THE PREFERRED EMBODIMENTS

The above and other objects, features and advantages of this disclosure will become apparent from the following detailed description taken with the accompanying drawings.

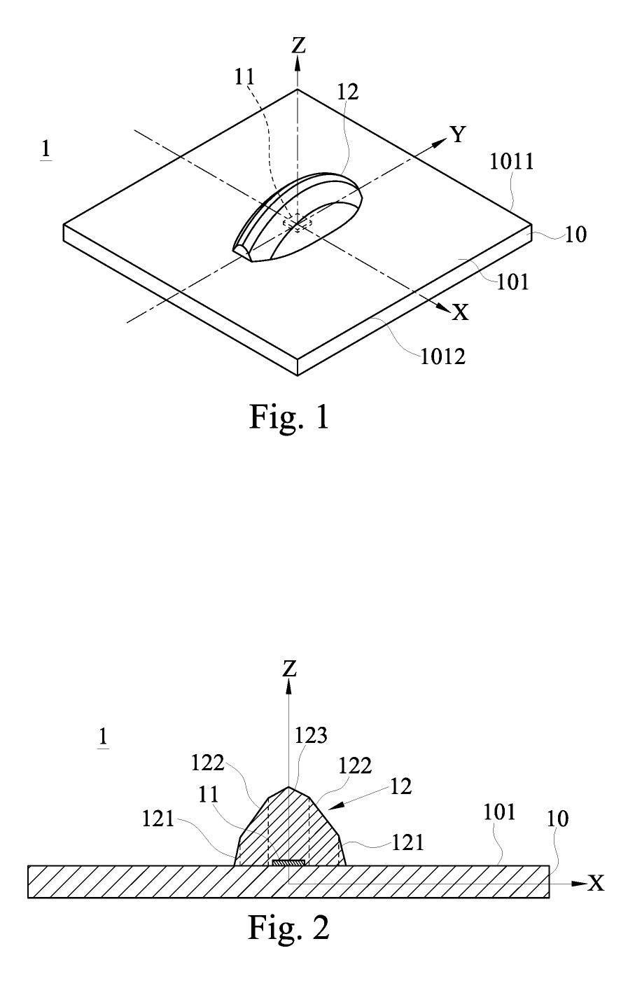

To simplify the structural design of the automotive lamp effectively, the inventor of the present invention applied the concept of the optical design of the LED light source to form a rectangular illumination light pattern when the LED light source is lit. With reference to FIGS. 1 to 7 for a perspective view, a cross-sectional view in the x-axis, a cross-sectional view in the y-axis, a first light distribution curve, a second light distribution curve, and a schematic view of an application of a primary optics light source with a rectangular light pattern in accordance with the first embodiment of the present invention respectively, the primary optics light source with a rectangular light pattern 1 comprise a substrate 10, an LED chip 11 and an encapsulated package 12, and the LED chip 11 is installed on a surface 101 of the substrate 10, and the encapsulated package 12 covers the LED chip 11 to fix the LED chip 11 to the substrate 10.

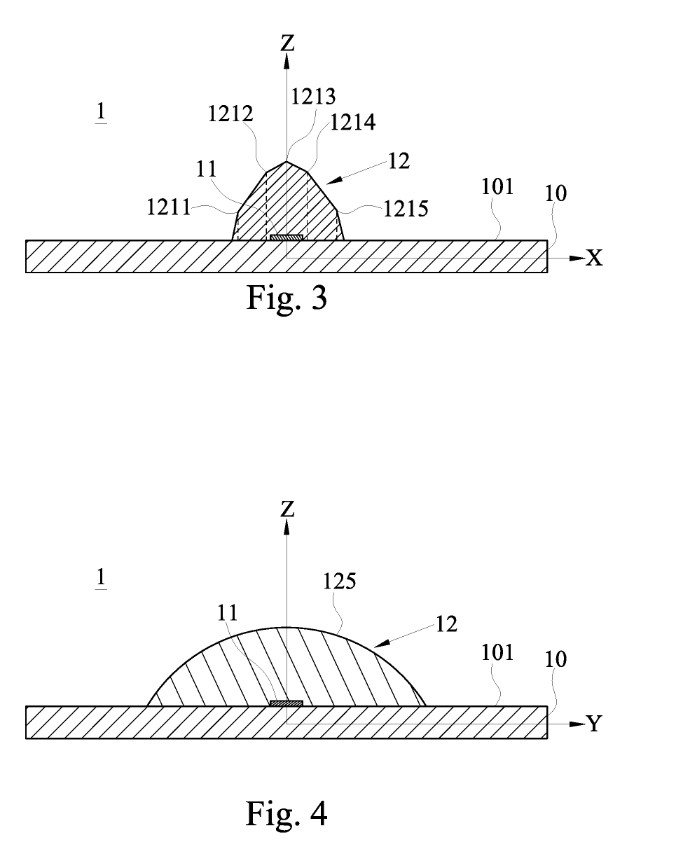

For the purpose of depicting the present invention, the x-axis and the y-axis in FIGS. 1-3 are two dimensional coordinates which are perpendicular to each other; and a plane formed by the x-axis and the y-axis is assigned to be parallel to a plane of the substrate provided for installing the LED chip. With reference to FIGS. 1 and 2, the primary optics light source 1 is characterized in that a cross-section profile of the encapsulated package in x-axis is a compound curve. Compound curve is defined as a curve having multiple arcs of successively different radii joined tangentially without reversal of curvature. In the present invention, the compound curve has three pairs of arcs of successively different radii joined tangentially without reversal of curvature. Since the compound curve is a discontinuous curve, the points at which the arcs are connected with one another form discontinuities. These discontinuities, in mathematical term, are points that resemble sharp turns at which the slope cannot be determined. In the present application, the compound curve comprises five discontinuities 1211, 1212, 1213, 1214, and 1215 (please refer to FIG. 3). With reference to FIG. 4, the cross-section of the encapsulated package of the present invention in y-axis comprises a hyperbolic curve 125, which has consistent sign of curvature. Referring to FIG. 2, in some embodiment, the compound curve may comprise a pair of first arcs 121, a pair of second arcs 122 and a pair of third arcs 123; these cars are sequentially arranged from the substrate 10 and on a cross-section of the encapsulated package 12 in the x-axis, and the pair of first arcs 121 are disposed opposite to each other and extended from the substrate 10 to couple the pair of second arc 122, and the pair of second arcs 122 are also disposed opposite to each other and coupled to the pair of third arcs 123. The pair of first arcs 121, the pair of second arcs 122 and the pair of third arcs 123 are all arc shaped as shown in FIG. 2. It is worth mentioning that the arcs in the present application are design to have large radii/small curvature; and thus, they appear to be straight lines in the figures. Furthermore, as shown in FIG. 4, a cross-section of the encapsulated package 12 in the y-axis resembles a hyperbolic curve 125.

Please refer to FIG. 1, the LED chip 11 is fixed onto a surface 101 of the substrate 10, and the LED chip 11 acts as the origin, and the axial direction parallel to a first side 1011 of the surface 101 is the x-axis, and the axial direction of a second side 1012 of the surface 101 is the y-axis. The light output direction of the primary optics light source 1 is the z-axis perpendicular to the x-axis and the y-axis simultaneously, and the whole encapsulated package 12 is tapered along the z-axis.

Preferably, the encapsulated package 12 is made of silicone to achieve the effects of packaging the LED chip 11 conveniently, outputting a light, and adjusting the light pattern of the outputted light effectively. To provide a better bonding strength between the encapsulated package 12 and the substrate 10, an adhesive is coated onto the substrate 10 before the encapsulated package 12 is combined with the substrate 10, and the adhesive is provided for enhancing the fixing force between the encapsulated package 12 and the substrate 10.

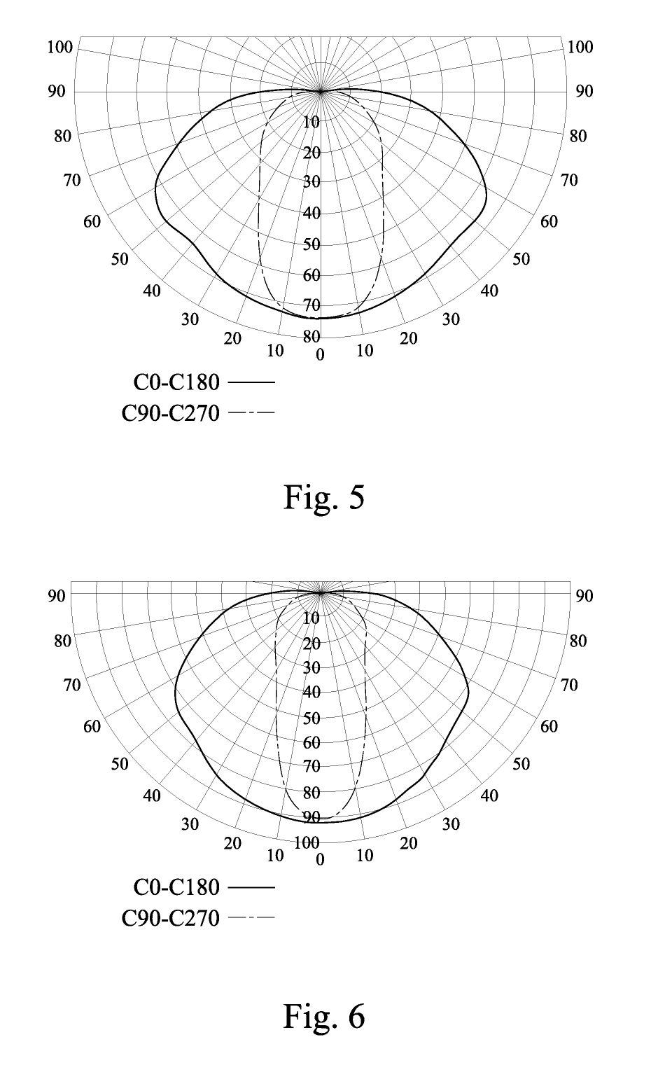

In FIG. 5, when the inventor of the present invention adopts an LED chip 11 with a size of 55 mil and the encapsulated package 12 in the aforementioned shape, experimental results show that after a light of the LED chip 11 is outputted through the encapsulated package 12, the rectangular light pattern A of the primary optics light source 1 has an aspect ratio falling within a range of 3.6:1-3.9:1, and further measurements show that the abduction angle range of a plane of the polar coordinate C0-C180 of the rectangular light pattern A is approximately equal to 150 degrees, and the abduction angle range of a plane of the polar coordinate C90-C270 is approximately equal to 38.5 degrees, such that the rectangular light pattern A has an aspect ratio of 3.9:1 which is in compliance with the aforementioned range.

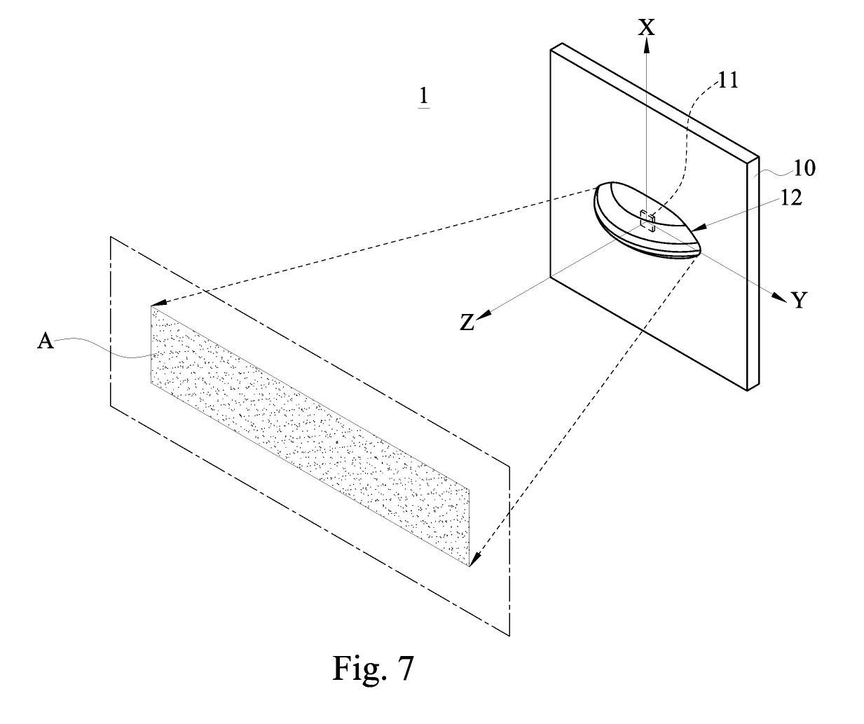

In FIG. 6, the inventor of the present invention adopts another LED chip 11 with a size of 38 mil and the encapsulated package 12 with a shape matching the aforementioned shape, and experimental results show that the rectangular light pattern A of the primary optics light source 1 formed after a light of the LED chip 11 is outputted through the encapsulated package 12 has an aspect ratio falling within a range of 5.45:1-5.75:1, and further measurements show that the abduction angle range of a plane of the polar coordinate C0-C180 of the rectangular light pattern A is approximately equal to 142 degrees, and the abduction angle range of a plane of the polar coordinate C90-C270 of the rectangular light pattern A is approximately equal to 25 degrees, so that the rectangular light pattern A has an aspect ratio of 5.68:1 which is in compliance with the aforementioned range. With reference to FIG. 7 for the schematic view of a rectangular light pattern A formed and projected from the primary optics light source 1 after the primary optics light source 1 is driven. The primary optics light source 1 outputs light in the z-axis, and the formed rectangular light pattern A has an aspect ratio substantially equal to 4:1.

Since the practical applications of the primary optics light source 1 are limited by special optical requirements or the requirements for applying the automotive lamp, therefore the specification of the LED chip 11 is also limited or specified by the foregoing contents. Even if the specification of the LED chip 11 is changed, the encapsulated package 12 is capable of maintaining the rectangular shape of the light pattern projected from the primary optics light source 1 to comply with the application requirements, so as to achieve the effect of providing simpler and easier elements for the lamp design. In addition, the size of the encapsulated package 12 may be increased or decrease in equal proportions according to the aforementioned shape in order to maintain the light pattern projected from the primary optics light source 1 in the rectangular shape. Obviously, the primary optics light source 1 of the present invention has excellent adjustability. After the size of the encapsulated package 12 is changed in equal proportions the rectangular light pattern still can be provided.

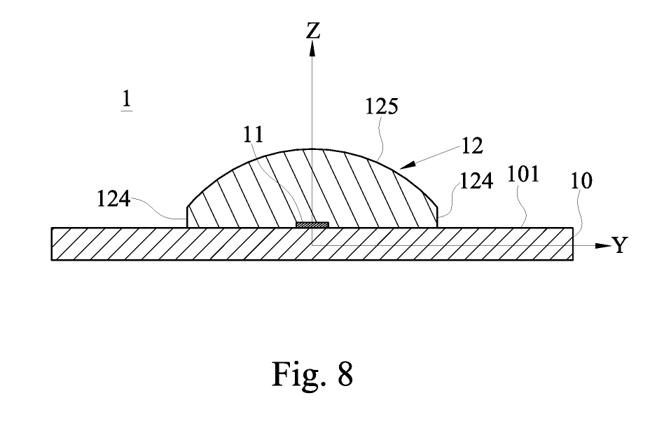

With reference to FIG. 8, a cross-sectional view in the y-axis of the second preferred embodiment of the present invention is shown. In some instances, the size of the encapsulated package 12 may be limited in actual applications of the primary optics light source 1 to cope with various different automotive lamps. Even if the primary optics light source 1 of the present invention is applied to an automotive lamp with a narrow installation space, both ends of the encapsulated package 12 may be reduced slightly to decrease the total length along the y-axis without affecting light pattern projected from the primary optics light source. When it is necessary to reduce the length of the encapsulated package 12 in the y-axis, both ends of the encapsulated package 12 are removed, so that the cross-section of the encapsulated package 12 in the y-axis has a pair bent section 124.

In the second embodiment, when an LED chip 11 with a size of 55 mil is used, the measured rectangular light pattern of the primary optics light source 1 has an aspect ratio falling within a range of 2.25:1-2.55:1. When an LED chip 11 with a size of 38 mil is used, the measured rectangular light pattern of the primary optics light source 1 has an aspect ratio falling within a range of 3.5:1-3.8:1. Therefore, the size of encapsulated package 12 of the primary optics light source 1 may be increased or decreased in equal proportions according to the previous preferred embodiment, or the length of the encapsulated package 12 in the y-axis may be changed to comply with the different specifications and requirements of various automotive lamps, and maintained the projected light pattern in a rectangular shape effectively. In addition, the fixing force between the encapsulated package 12 and the substrate 10 may be enhanced. Before the encapsulated package 12 is combined with the substrate 10, an adhesive is coated onto the substrate 10 to improve the bonding strength between the encapsulated package 12 and the substrate 10, and the encapsulated package 12 may be made of silicone to achieve the effects of light transmission and package protection.

In summation of the description above, the primary optics light source 1 of the present invention is capable of directly forming a rectangular light pattern projected from a primary optics light source without requiring a further secondary optics design to achieve the effects of improving the application performance of the light source, skipping the complicated structure design of the automotive lamp, and reducing the using quantity of other optical elements to reduce the total volume of the lamp. With the special stylish appearance of the encapsulated package 12, the light emitted from the LED chip 11 can be adjusted effectively to form the rectangular light pattern A directly and maintain an excellent light output quality. To cope with the installation environment of the primary optics light source 1, the shape of the rectangular light pattern A of the primary optics light source 1 and the same aspect ratio of the rectangular light pattern A can still be maintained when the size of the encapsulated package 12 is increased or decreased, or the specification of the LED chip 11 is changed. In a special automotive lamp installation environment, such as a very narrow space for installing an automotive lamp of the primary optics light source 1, the length of the encapsulated package 12 in the y-axis may be reduced, so that the shape of the rectangular light pattern A projected from the primary optics light source 1 will not be changed or affected. Therefore, the present invention improves the inconvenience of the conventional automotive lamp that requires a secondary optics design to form the specific light pattern and the invention has the effect of lowering the design and development costs of the automotive lamp.

What is claimed is:

1. A primary optics light source with a rectangular light pattern, having a substrate, an LED chip and an encapsulated package, and the LED chip being installed on the substrate, and the encapsulated package covering the LED chip to fix the LED chip to the substrate, characterized in that a cross-section profile of the encapsulated package in x-axis is a compound curve having three pairs of arcs of successively different radii joined tangentially without reversal of curvature, the compound curve comprises five discontinuities where slopes cannot be defined at the five discontinuities, and a cross-section of the encapsulated package in y-axis comprises a hyperbolic curve, wherein the x-axis and the y-axis are perpendicular to each other, and a plane included between the x-axis and the y-axis is parallel to a plane of the substrate provided for installing the LED chip.

2. The primary optics light source with a rectangular light pattern according to claim 1, wherein when the LED chip has a size of 55 mil, the rectangular light pattern has an aspect ratio falling within a range of 3.6:1-3.9:1.

3. The primary optics light source with a rectangular light pattern according to claim 1, wherein when the LED chip has a size of 38 mil, the rectangular light pattern has an aspect ratio falling within a range of 5.45:1-5.75:1.

4. The primary optics light source with a rectangular light pattern according to claim 1, wherein before the encapsulated package is combined with the substrate, the substrate includes an adhesive for improving the bonding strength between the encapsulated package and the substrate.

5. The primary optics light source with a rectangular light pattern according to claim 1, wherein the encapsulated package is made of silicone.

6. A primary optics light source with a rectangular light pattern, having a substrate, an LED chip and an encapsulated package, and the LED chip being installed on the substrate, and the encapsulated package covering the LED chip to fix the LED chip to the substrate, characterized in that a cross-section profile of the encapsulated package in x-axis is a compound curve having three pairs of arcs of successively different radii joined tangentially without reversal of curvature, the compound curve is comprised of a pair of first arcs, a pair of second arcs, a pair of third arcs, and five discontinuities where slopes cannot be defined at the five discontinuities, the pair of first arcs is disposed opposite to each other and extended from the substrate to couple with the pair of second arcs, and the pair of second arcs are also disposed opposite to each other and coupled to the pair of third arcs, and a cross-section of the encapsulated package in the y-axis comprises a hyperbolic curve, thereby a light of the LED chip is emitted to the outside through the encapsulated package to form a rectangular light pattern; wherein the x-axis and the y-axis are perpendicular to each other, and a plane included between the x-axis and the y-axis is parallel to a plane of the substrate provided for installing the LED chip.

7. The primary optics light source with a rectangular light pattern according to claim 6, wherein when the LED chip has a size of 55 mil, the rectangular light pattern has an aspect ratio falling within a range of 3.6:1-3.9:1.

8. The primary optics light source with a rectangular light pattern according to claim 6, wherein when the LED chip has a size of 38 mil, the rectangular light pattern has an aspect ratio falling within a range of 5.45:1-5.75:1.

9. The primary optics light source with a rectangular light pattern according to claim 6, wherein before the encapsulated package is combined with the substrate, the substrate includes an adhesive for improving the bonding strength between the encapsulated package and the substrate.

10. The primary optics light source with a rectangular light pattern according to claim 6, wherein the encapsulated package is made of silicone.

11. A primary optics light source with a rectangular light pattern, having a substrate, an LED chip and an encapsulated package, and the LED chip being installed on the substrate, and the encapsulated package covering the LED chip to fix the LED chip to the substrate, characterized in that a cross-section profile of the encapsulated package in x-axis is a compound curve having three pairs of arcs of successively different radii joined tangentially without reversal of curvature, the compound curve is comprised of a pair of first arcs, a pair of second arcs, a pair of third arcs, and five discontinuities where slopes cannot be defined at the five discontinuities, the pair of first arcs is disposed opposite to each other and extended from the substrate to couple with the pair of second arcs, and the pair of second arcs are also disposed opposite to each other and coupled to the pair of third arcs, and a cross-section of the encapsulated package in the y-axis comprises a hyperbolic curve, thereby a light of the LED chip is emitted to the outside through the encapsulated package to form a rectangular light pattern; wherein the x-axis and the y-axis are perpendicular to each other, and a plane included between the x-axis and the y-axis is parallel to a plane of the substrate provided for installing the LED chip, wherein the hyperbolic curve further comprises a pair of bent sections, the pair of bent sections is disposed opposite to each other and extended from the substrate to couple with both ends of the hyperbolic curve respectively, and the bent sections are perpendicular to the substrate.

12. The primary optics light source with a rectangular light pattern according to claim 11, wherein when the LED chip has a size of 55 mil, the rectangular light pattern has an aspect ratio falling within a range of 2.25:1-2.55:1.

13. The primary optics light source with a rectangular light pattern according to claim 11, wherein when the LED chip has a size of 38 mil, the rectangular light pattern has an aspect ratio falling within a range of 3.5:1-3.8:1.

14. The primary optics light source with a rectangular light pattern according to claim 11, wherein before the encapsulated package is combined with the substrate, the substrate includes an adhesive for improving the bonding strength between the encapsulated package and the substrate.

15. The primary optics light source with a rectangular light pattern according to claim 11, wherein the encapsulated package is made of silicone.
